(19) United States
(12) Patent Application Publication
(10) Pub. No.: US 2026/0310062 A1
(43) Pub. Date: Oct. 8, 2026

(54) METHOD OF AND DEVICE FOR GENERATING LAYOUT DIAGRAM

(71) Applicant: Taiwan Semiconductor Manufacturing Company, Ltd., Hsinchu (TW)

(72) Inventors: Jia-Guei JOU, Hsinchu (TW); Yu-Tung CHEN, Hsinchu (TW); Ying-Ju LIN, Hsinchu (TW); Wei-Lin CHU, Hsinchu (TW)

(73) Assignee: Taiwan Semiconductor Manufacturing Company, Ltd., Hsinchu (TW)

(21) Appl. No.: 19/170,642

(22) Filed: Apr. 4, 2025

(51) Int. Cl. G03F 1/36; G06F 30/398

(52) U.S. Cl. CPC G03F 1/36; G06F 30/398

(57) ABSTRACT

An embodiment method of generating a via layout diagram of a layout plan of a semiconductor device prior to application of an optical proximity correction (OPC) process includes obtaining an initial layout plan that includes a first layout pattern indicative of a first conductive structure, a second layout pattern indicative of a second conductive structure, and an initial via layout pattern indicative of electrically coupling of the first conductive structure and the second conductive structure. The method includes deriving a first estimated pattern based on the first layout pattern, deriving a second estimated pattern based on the second layout pattern, and determining a modified via layout pattern indicative of a via structure based on the first estimated pattern and the second estimated pattern. The modified via layout pattern has a curved shape prior to the application of the OPC process.

### BACKGROUND

The semiconductor integrated circuit (IC) industry has experienced rapid growth. In the course of IC evolution, functional density (i.e., the number of interconnected devices per chip area) has generally increased while geometric size (i.e., scale of the smallest component (or line) that can be created using a fabrication process, measurable as a critical dimension in some applications) has decreased. This scaling-down process generally provides benefits by increasing production efficiency and reducing associated costs. However, the resistance of a conductive structure in a semiconductor device increases as its width or cross-sectional area (perpendicular to the direction of current) decreases.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an integrated circuit (IC) manufacturing system, and an IC manufacturing flow associated therewith, in accordance with some embodiments.

FIG. 2 is a cross-sectional view of a semiconductor device, in accordance with some embodiments.

FIGS. 3A-3D are plan views of various layout patterns or estimated patterns for a layer of a semiconductor device at different stages of a mask data preparation process, in accordance with some embodiments.

FIGS. 4A-4C are plan views of various layout patterns or estimated patterns for a first metallization layer, a second metallization layer, and a via layer of a semiconductor device, in accordance with some embodiments.

FIGS. 5A-5B are plan views of via layout patterns for a via layer of a semiconductor device in view of estimated patterns for a first metallization layer and a second metallization layer of the semiconductor device, in accordance with some embodiments.

FIGS. 6A-6B are plan views of portions of photomask examples for a via layer of a semiconductor device based on the examples in FIGS. 5A-5B, in accordance with some embodiments.

FIG. 7 is a block diagram of a portion of a mask data preparation process, in accordance with some embodiments.

FIGS. 8A-8C are plan views of additional layout pattern examples for a first metallization layer, a second metallization layer, and a via layer having curved patterns, in accordance with some embodiments.

FIG. 9 is a flowchart of a method of generating a via layout diagram of a layout plan of a semiconductor device prior to application of an optical proximity correction (OPC) process, in accordance with some embodiments.

FIG. 10 is a block diagram of an electronic design automation (EDA) system in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” or the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

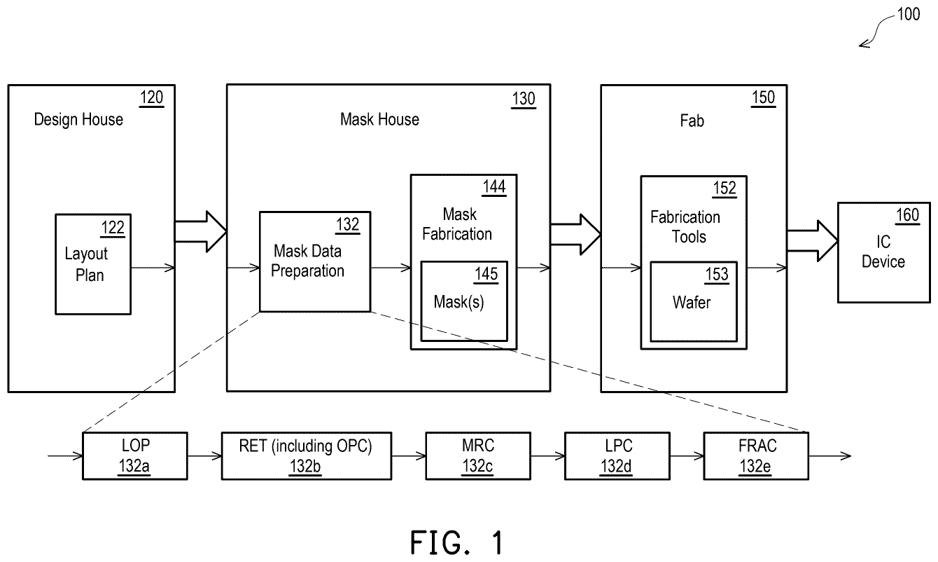

FIG. 1 is a block diagram of an integrated circuit (IC) manufacturing system 100, and an IC manufacturing flow associated therewith, in accordance with some embodiments. In some embodiments, based on a layout plan for a semiconductor device, at least one of (A) one or more photomasks or (B) one or more features in a layer of the semiconductor device are fabricated using manufacturing system 100.

In FIG. 1, IC manufacturing system 100 includes entities, such as a design house 120, a mask house 130, and an IC manufacturer/fabricator (fab) 150, that interact with one another in the design, development, and manufacturing cycles and/or services related to manufacturing an IC device 160. The entities in system 100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 120, mask house 130, and IC fab 150 are owned by a single larger company. In some embodiments, two or more of design house 120, mask house 130, and IC fab 150 coexist in a common facility and use common resources.

Design house (or design team) 120 generates a layout plan 122 of an IC design. In some embodiments, layout plan 122 includes one or more layout diagrams, and each layout diagram includes various geometrical patterns designed for an IC device 160 (e.g., a semiconductor device). The geometrical patterns correspond to patterns of metal, oxide, or semiconductor layers that make up the various components of IC device 160 to be fabricated. The various layers combine to form various IC features. For example, a portion of layout plan 122 includes layout patterns indicative of various IC features, such as an active region, gate electrode, source and drain, metal lines or vias of an interlayer interconnection, and openings for bonding pads, to be formed based on a semiconductor substrate (such as a silicon wafer) and various material layers disposed on the semiconductor substrate. Design house 120 implements a proper design procedure to form layout plan 122. The design procedure includes one or more of logic design, physical design or place and route. In some embodiments, each layout diagram of layout plan 122 is presented in one or more data files having information of the geometrical patterns. For example, each layout diagram of layout plan 122 can be expressed in a GDSII file format or DFII file format.

Mask house 130 includes mask data preparation 132 and mask fabrication 144. Mask house 130 uses layout plan 122 to manufacture one or more masks 145 to be used for fabricating the various layers of IC device 160 according to layout plan 122. Mask house 130 performs mask data preparation 132, where layout plan 122 is translated into a representative data file (RDF). Mask data preparation 132 provides the RDF to mask fabrication 144. Mask fabrication 144 includes a mask writer. A mask writer converts the RDF to an image on a substrate, such as a mask (reticle) 145 or a semiconductor wafer 153. Layout plan 122 is manipulated by mask data preparation 132 to comply with particular characteristics of the mask writer and/or requirements of IC fab 150. In FIG. 1, mask data preparation 132 and mask fabrication 144 are illustrated as separate elements. In some embodiments, mask data preparation 132 and mask fabrication 144 can be collectively referred to as mask data preparation.

In some embodiments, mask data preparation 132 includes various stages, including one or more of a logic operation (LOP) stage 132a, a resolution enhancement technique (RET) (RET) stage 132b, a mask rule checker (MRC) stage 132c, and a lithography process checking (LPC) stage 132d. In some embodiments, each one of the above-noted stages receives an input layout diagram from a previous stage in the GDSII file format or DFII file format, and output a processed result as an output layout diagram to a subsequent stage in the GDSII file format or DFII file format. In some embodiments, some stages and/or operations described herein are omitted, and some additional stages and/or operations are included in mask data preparation 132. In some embodiments, these stages are performed based on an order different from the example in FIG. 1.

In some embodiments, LOP stage 132a corresponds to modifying an input layout diagram (e.g., a layout diagram of the layout plan 122 from design house 120) according to manufacturing rules. In some embodiments, LOP stage 132a includes checking whether the input layout diagram meets a set of rules derived based on various manufacturer constraints and modifying the input layout diagram accordingly to obtain an output layout diagram that meets the set of rules.

In some embodiments, RET stage 132b corresponds to modifying the input layout diagram (e.g., the output layout diagram from LOP stage 132a) to obtain an output layout diagram that compensates for various limitations in lithographic processes used to manufacture IC device 160. In some embodiments, RET stage 132b includes a rule-based optical proximity correction (OPC) process and/or model-based OPC process that correspond to using lithography enhancement techniques to compensate for image errors, such as those that can arise from diffraction, interference, other process effects or the like. In some embodiments, RET stage 132b further includes one or more other enhancement techniques, such as off-axis illumination, sub-resolution assist features, phase-shifting masks, other suitable techniques, or the like or combinations thereof. In some embodiments, inverse lithography technology (ILT) is also used, which treats OPC as an inverse imaging problem.

In some embodiments, MRC stage 132c corresponds to checking the layout diagram that has undergone processes in RET stage with a set of mask creation rules, which contain certain geometric and/or connectivity restrictions to ensure sufficient margins, to account for variability in semiconductor manufacturing processes, or the like. In some embodiments, MRC stage 132c also corresponds to modifying the layout diagram to compensate for photolithographic implementation effects during mask fabrication 144, which may undo part of the modifications performed by OPC of RET stage 132b in order to meet mask creation rules.

In some embodiments, LPC stage 132d corresponds to simulating processing that will be implemented by IC fab 150 to fabricate IC device 160. The simulation at LPC stage 132d is based on the layout diagram from the previous stage (e.g., MRC stage 132c) to create one or more simulated manufactured features representing the corresponding portions of the IC device 160 to be manufactured based on the layout diagram from MRC stage 132c. The processing parameters in LPC simulation include parameters associated with various processes of the IC manufacturing cycle, parameters associated with tools used for manufacturing the IC, and/or other aspects of the manufacturing process. The simulation at LPC stage 132d takes into account various factors, such as aerial image contrast, depth of focus (DOF), mask error enhancement factor (MEEF), other suitable factors, or the like or combinations thereof. In some embodiments, after the one or more simulated manufactured features have been created at LPC stage 132d, if the size, shape, and/or spatial relationship of the simulated features fail to meet the design rules or design specification, the process proceeds to repeat RET stage 132b and/or MRC stage 132c to further refine the layout diagram.

In this example, after LPC stage 132d, mask data preparation 132 further includes a fracturing process (FRAC) stage 132e. In some embodiments, FRAC stage 132e receives an input layout diagram from a previous stage (e.g., LPC stage 132d) in the GDSII file format or DFII file format and outputs a processed result to a subsequent stage (e.g., mask fabrication 144) as a mask file in an RDF format. In some embodiments, FRAC stage 132e corresponds to “fracturing” the designed features into polygons or other component shapes suitable for mask production.

After mask data preparation 132 and during mask fabrication 144, a mask 145 or a group of masks 145 (collectively referred to as “mask(s) 145”) are fabricated based on the modified layout diagram and/or the mask file converted from the modified layout diagram. In some embodiments, mask fabrication 144 includes performing one or more lithographic exposures based on the modified layout diagram and/or mask file from mask data preparation 132. In some embodiments, an electron-beam (e-beam) or a mechanism of multiple e-beams is used to form a pattern on a mask (photomask or reticle) (e.g., mask(s) 145) based on the modified layout diagram and/or the mask file. Mask(s) 145 can be formed in various technologies. In some embodiments, mask(s) 145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask(s) 145 includes a transparent substrate (e.g., fused quartz) and an opaque material (e.g., chromium) coated in the opaque regions of the binary mask. In another example, mask(s) 145 is formed using a phase shift technology. In a phase shift mask (PSM) version of mask(s) 145, various features in the pattern formed on the phase shift mask are configured to have proper phase difference to enhance the resolution and imaging quality. In various examples, the phase shift mask is attenuated PSM or alternating PSM. The mask(s) generated by mask fabrication 144 is used in a variety of processes. For example, such a mask(s) is used in an ion implantation process to form various doped regions in semiconductor wafer 153, in an etching process to form various etching regions in semiconductor wafer 153, and/or in other suitable processes.

IC fab 150 is an IC fabrication business that includes one or more manufacturing facilities for the fabrication of a variety of different IC products. In some embodiments, IC Fab 150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 150 includes fabrication tools 152 configured to execute various manufacturing operations on semiconductor wafer 153 such that IC device 160 is fabricated in accordance with the mask(s), e.g., mask(s) 145. In various embodiments, fabrication tools 152 include one or more of a wafer stepper, an ion implanter, a photoresist coater, a process chamber, e.g., a chemical vapor deposition (CVD) chamber or low-pressure chemical vapor deposition (LPCVD) furnace, a chemical mechanical polishing (CMP) system, a plasma etch system, a wafer cleaning system, or other manufacturing equipment capable of performing one or more suitable manufacturing processes as discussed herein.

IC fab 150 uses mask(s) 145 fabricated by mask house 130 to fabricate IC device 160. Thus, IC fab 150 at least indirectly uses one or more layout diagrams of layout plan 122 to fabricate IC device 160. In some embodiments, semiconductor wafer 153 is fabricated by IC fab 150 using mask(s) 145 to form IC device 160. In some embodiments, the IC fabrication includes performing one or more lithographic exposures based at least indirectly on one or more layout diagrams of layout plan 122. Semiconductor wafer 153 includes a silicon substrate or other proper substrate having material layers formed thereon. Semiconductor wafer 153 further includes one or more of various doped regions, dielectric features, multilevel interconnects, or the like (formed at subsequent manufacturing steps).

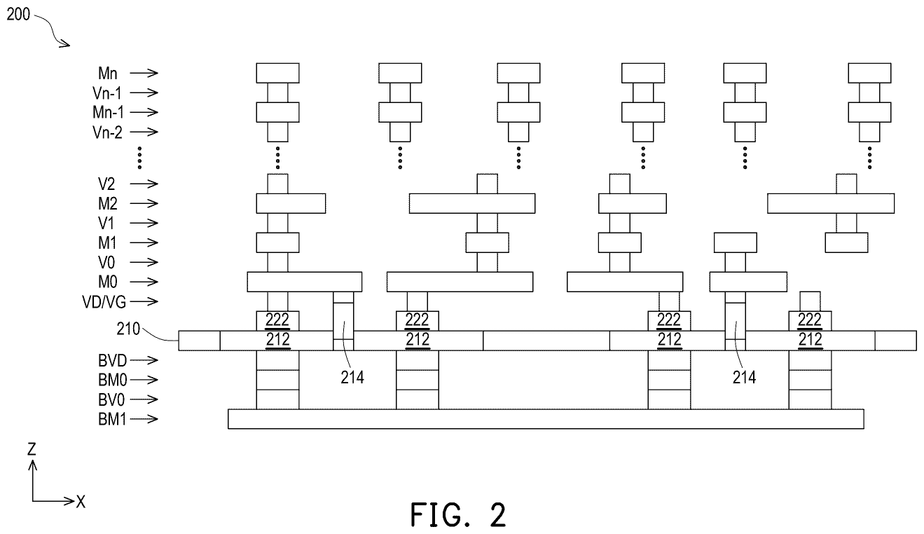

FIG. 2 is a cross-sectional view of a semiconductor device 200, in accordance with some embodiments. In some embodiments, semiconductor device 200 corresponds to IC device 160 manufactured based on the example in FIG. 1. In some embodiments, the cross-sectional view is a simplified cross-sectional view, with many features simplified or not depicted.

Semiconductor device 200 in FIG. 2 includes a substrate 210 with active regions 212 and gate structures 214 formed on or partially in substrate 210. In this example, semiconductor device 200 includes metal-to-drain/source (MD) structures 222 coupled to the active regions 212. In this example, semiconductor device 200 includes via-to-drain/source (VD) structures coupled to MD structures 222 and via-to-gate (VG) structures coupled to gate structures 214 at a VD/VG layer above substrate 210 (with respect to a direction Z). In some embodiments, semiconductor device 200 further includes a plurality of metallization layers (e.g., M0, M1, M2, ..., Mn-1, and Mn layers) and a plurality of via layers (e.g., V0, V1, V2, . . . , Vn-2, and Vn-1 layers) over the VD/VG layer and substrate 210 (n being a positive integer). In some embodiments, a number of metallization layers over substrate 210 ranges from 8 to 14. In some embodiments, Vn-1 layer denotes the via structures between and connecting conductive structures (e.g., conductive lines) in Mn-1 layer and Mn layer. In some embodiments, M0 layer denotes the first metallization layer above substrate 210. In some embodiments, the plurality of metallization layers and the plurality of via layers include a conductive material including copper, aluminum, gold, tungsten, a combination thereof, or the like.

Semiconductor device 200 in FIG. 2, as a non-limiting example, further includes conductive structures disposed under substrate 210. For example, semiconductor device 200 further includes backside metallization layers BM0 and BM1 and backside via layers BVD and BV0. In this example, BVD layer denotes backside via structures between and connecting active regions 212 and backside conductive structures (e.g., conductive lines) in BM0 layer; and BV0 layer denotes backside via structures between and connecting backside conductive structures (e.g., conductive lines) in BM0 layer and BM1 layer. In some embodiments, BM0 layer denotes the first metallization layer under substrate 210. In this example, semiconductor device 200 includes two backside metallization layers and corresponding via layers. In some embodiments, a number of backside metallization layers under substrate 210 ranges from 2 to 6. In some embodiments, a portion or all of the backside conductive structures (e.g., backside metallization layers BM0 and BM1 and backside via layers BVD and BV0) are at least partially embedded in substrate 210. In some embodiments, backside metallization layers BM0 and BM1 and backside via layers BVD and BV0 include a conductive material including copper, aluminum, gold, tungsten, a combination thereof, or the like. In some other embodiments, a semiconductor device does not include any backside conductive structures.

In some embodiments, semiconductor device 200 includes one or more redistribution layers and conductive pad structures (not in FIG. 2) over the one or more redistribution layers. In some embodiments, semiconductor device 200 further includes conductive terminal structures (e.g., conductive bumps, copper pillar bumps, solder bumps, or the like, not in FIG. 2) over the conductive pad structures. In some embodiments, semiconductor device 200 also includes one or more backside redistribution layers and backside conductive pad structures (not in FIG. 2) under the one or more backside redistribution layers. In some embodiments, semiconductor device 200 also includes backside conductive terminal structures (e.g., conductive bumps, copper pillar bumps, solder bumps, or the like, not in FIG. 2) under the backside conductive pad structures.

In some embodiments, semiconductor device 200 includes transistors formed based on active regions 212 and gate structures 214 in a front-end-of-line (FEOL) portion of semiconductor device 200. In some embodiments, one or more functional circuit blocks are formed based on electrically connecting the transistors in the FEOL portion of semiconductor device 200. In some embodiments, a portion of semiconductor device 200 at and above a given metallization layer (e.g., a M5 layer and above) correspond to a back-end-of-line (BEOL) portion of semiconductor device 200. In some embodiments, additional transistors, capacitors, resistors, inductors, a combination thereof, or the like, are also formed in the BEOL portion of semiconductor device 200.

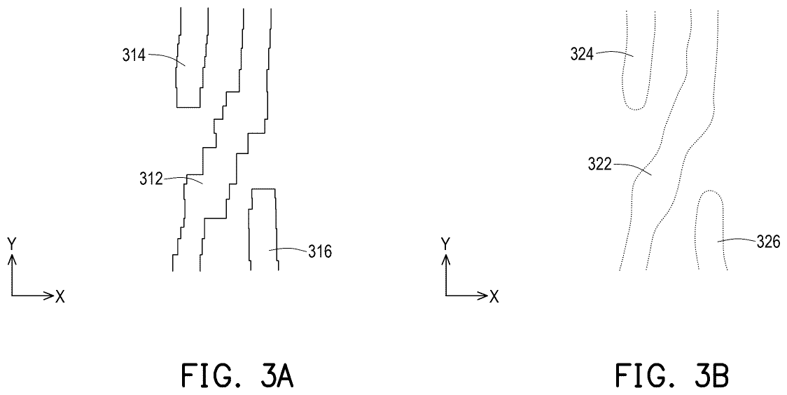

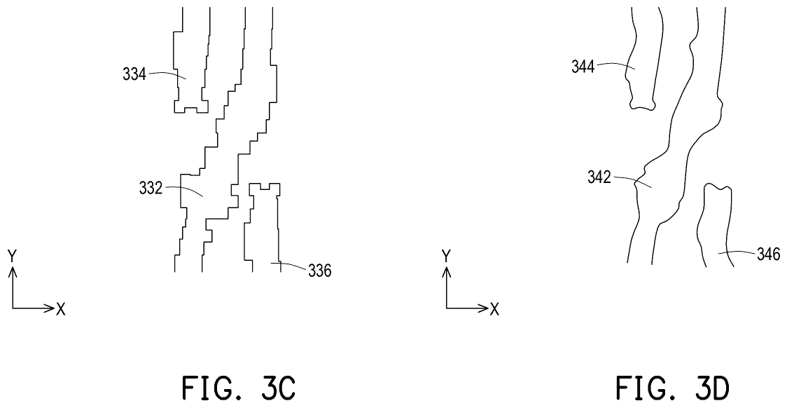

FIG. 3A is a plan view of a set of layout patterns for a layer of a semiconductor device, in accordance with some embodiments. FIG. 3 includes a portion of three layout patterns 312, 314, and 316, with the upper portions and the lower portions thereof truncated for simplicity. In this example, layout patterns 312, 314, and 316 correspond to a layout pattern for a metallization layer indicative of a conductive structure of the metallization layer of the semiconductor device.

In this example, layout patterns 312, 314, and 316 have Manhattanized curvilinear shapes based on Manhattanized lines. In some application, “Manhattanized lines” correspond to the lines extending along a first horizontal direction (e.g., an X direction) or a second horizontal direction (e.g., a Y direction), where the first horizontal direction and the second horizontal direction are perpendicular to each other. As a result, a Manhattanized curvilinear shape corresponds to a shape having sides formed based on staircase-like line segments.

The layout patterns having Manhattanized curvilinear shapes in FIG. 3A correspond to a type of non-straight layout patterns as a non-limiting example. In some embodiments, as another type of non-straight layout patterns, a layout pattern includes a curved shape having the contour formed based on parametric equation(s) and parameter(s) (also referred to as having a parametric curve shape in this disclosure).

FIG. 3B is a plan view of a set of estimated patterns 322, 324, and 326 derived or derivable from layout patterns 312, 314, and 316 in FIG. 3A, in accordance with some embodiments. In some embodiments, estimated patterns 322, 324, and 326 indicate the estimated size and shape of resulting features (represented by layout patterns 312, 314, and 316) of the semiconductor device, based on simulating how the mask(s) would be fabricated (e.g., with respect to the process of mask data preparation 132 and mask fabrication 144 in FIG. 1) and how the semiconductor device (e.g., IC device 160) would be manufactured (e.g., with respect to the process of IC fab 150). In some embodiments, estimated patterns 322, 324, and 326 are obtained at an LPC stage (e.g., LPC stage 132d in FIG. 1) after applying an OPC process on layout patterns 312, 314, and 316. In some embodiments, estimated patterns 322, 324, and 326 are obtained during an OPC process at an RET stage (e.g., RET stage 132b in FIG. 1) as a target image of the OPC process based on ILT.

FIG. 3C is a plan view of a set of layout patterns 332, 334, and 336 corresponding to the result of applying a first OPC process example on layout patterns 312, 314, and 316 in FIG. 3A, in accordance with some embodiments. In some embodiments, layout patterns 332, 334, and 336 have Manhattanized curvilinear shapes. FIG. 3D is a plan view of a set of layout patterns 342, 344, and 346 corresponding to the result of applying a second OPC process example on layout patterns 312, 314, and 316 in FIG. 3A, in accordance with some embodiments. In some embodiments, layout patterns 332, 334, and 336 have parametric curve shapes.

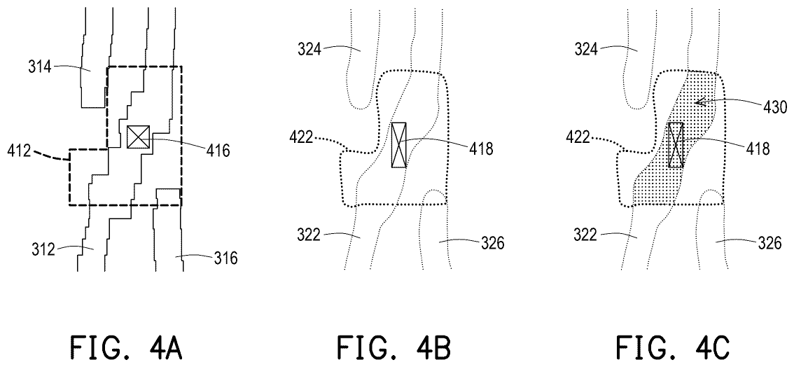

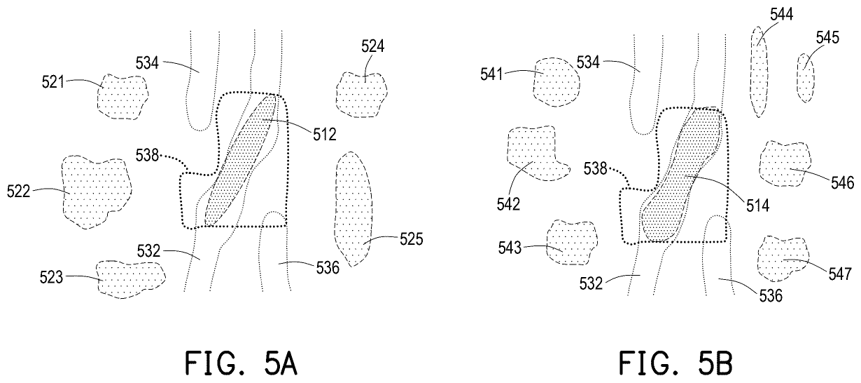

FIG. 4A is a plan view of various layout patterns included in a layout plan of a semiconductor device, in accordance with some embodiments. In this example, the layout patterns in FIG. 4A correspond to layout patterns prior to application of an OPC process. In some embodiments, the layout patterns in FIG. 4A are included in the corresponding layout diagrams from a design house (e.g., design house 120 in FIG. 1) before mask data preparation (e.g., mask data preparation 132 in FIG. 1).

FIG. 4A includes layout patterns 312, 314, and 316 that are included in a first metallization layout diagram of the layout plan for a first metallization layer of the semiconductor device, as described in the example of FIG. 3A. In some embodiments, layout patterns 312, 314, and 316 are indicative of conductive structures in the first metallization layer of the semiconductor device. FIG. 4A also includes a layout pattern 412 that is included in a second metallization layout diagram of the layout plan for a second metallization layer of the semiconductor device. In some embodiments, layout pattern 412 is indicative of a conductive structure in the second metallization layer of the semiconductor device over the first metallization layer. In this example, layout patterns 312, 314, 316, and 412 have Manhattanized curvilinear shapes. In some other examples, layout patterns corresponding to 312, 314, 316, and 412 have parametric curve shapes.

FIG. 4A further includes a via layout pattern 416 that is included in a via layout diagram of the layout plan for a via layer of the semiconductor device. In some embodiments, via layout pattern 416 is indicative of a via structure electrically connecting a conductive structure indicated by layout pattern 312 and a conductive structure indicated by layout pattern 412. In this example, via layout pattern 416 has a Manhattanized shape, such as a square shape or a rectangular shape.

FIG. 4B is a plan view of various estimated patterns and a modified via layout pattern 418, in accordance with some embodiments. FIG. 4B includes estimated patterns 322, 324, and 326 that are derivable from layout patterns 312, 314, and 316, as described in the example of FIG. 3B. FIG. 4B also includes an estimated pattern 422 that is derivable from layout pattern 412 in FIG. 4A. In this example, the layout patterns for the via layer are limited to Manhattanized shapes. In this example, because the layout patterns 312 and 412 have non-straight sides, via layout pattern 416 is replaceable with modified via layout pattern 418, which remains a Manhattanized shape with an enlarged area larger than that of via layout pattern 416. As a result, the resistance of a resulting via structure based on modified via layout pattern 418 would be lower than that of a counterpart via structure based on via layout pattern 416.

In FIG. 4B, estimated pattern 322 and estimated pattern 422 overlap each other and define an overlapped region 430, as further emphasized in FIG. 4C. In FIG. 4C, modified via layout pattern 418 is within overlapped region 430, and the area of overlapped region 430 is much greater than the area of modified via layout pattern 418. However, based on the layout patterns for the via layer being limited to Manhattanized shapes, a substantial portion of overlapped region 430 is not actually being utilized for the electrical connection between the conductive structure corresponding to estimated pattern 322 and the conductive structure corresponding to estimated pattern 422.

According to one or more embodiments of the present disclosure, for a via structure electrically connecting a first conductive structure under the via structure and a second conductive structure over the via structure, a via layout pattern indicative of the via structure has a curved shape (instead of a Manhattanized shape) prior to application of an OPC process. In some embodiments, the first conductive structure corresponds to a first estimated pattern derivable from a first layout pattern, the second conductive structure corresponds to a second estimated pattern derivable from a second layout pattern, and the first estimated pattern and the second estimated pattern overlap each other and define an overlapped region. In some embodiments, based on the via layout pattern having the curved shape, the size and shape of the via layout pattern can better fit the overlapped region in order to increase or maximize an area of the via layout pattern and to maximize the utilization of the area of the overlapped region for electrical connection. Accordingly, the resistance of the resulting via structure having a curved shape based on one or more embodiments in this disclosure can be further reduced compared to a counterpart having a Manhattanized shape.

FIG. 5A is a plan view of via layout patterns 512, 521, 522, 523, 524, and 525 (prior to application of an OPC process) for a via layer of a semiconductor device based on a first data preparation example in view of estimated patterns 532, 534, 536, and 538 for a first metallization layer and a second metallization layer of the semiconductor device, in accordance with some embodiments. In this non-limiting example, estimated patterns 532, 534, and 536 correspond to estimated patterns 322, 324, and 326 that are derivable based on layout patterns 312, 314, and 316 for the first metallization layer as described with respect to the examples in FIGS. 3A-3B and 4A-4B. In this non-limiting example, estimated layout pattern 538 corresponds to estimated layout pattern 422 that is derivable based on layout pattern 412 for the second metallization layer as described with respect to the examples in FIGS. 4A-4B.

In this non-limiting example, via layout pattern 512 is based on modifying via layout pattern 416 as described with respect to the example in FIG. 4A. In this non-limiting example, via layout pattern 512 prior to the application of the OPC process has an elliptical shape. Similar to the example described in view of FIG. 4C, estimated pattern 532 and estimated pattern 538 overlap each other and define an overlapped region (e.g., corresponding to overlapped region 430 in FIG. 4C). In some embodiments, via layout pattern 512 is determined by resizing, tilting, positioning, or a combination thereof, a base elliptical contour from a layout library based on reduction of a difference between the modified via layout pattern and the overlapped region. In some embodiments, the operations for determining via layout pattern 512 include creating an error function based on a difference between an area of an elliptical contour and the area of the overlapped region, and then tuning the elliptical contour according to the error function in order to minimize the difference.

Moreover, via layout patterns 521, 522, 523, 524, and 525 correspond to a set of dummy layout patterns for the via layer of the semiconductor device. In some embodiments, each one of the set of dummy layout patterns has a corresponding freeform shape. In some embodiments, the set of dummy layout patterns (i.e., via layout patterns 521, 522, 523, 524, and 525) is within a reference distance from via layout pattern 512. In some embodiments, the reference distance corresponds to an OPC ambit of the OPC process to be applied to the via layout patterns 512, 521, 522, 523, 524, and 525. In some embodiments, the set of dummy layout patterns (i.e., via layout patterns 521, 522, 523, 524, and 525) is omitted.

FIG. 5B is a plan view of via layout patterns 514, 541, 542, 543, 544, 545, 546, and 547 (prior to application of an OPC process) for a via layer of a semiconductor device based on a second data preparation example in view of estimated patterns 532, 534, 536, and 538 for a first metallization layer and a second metallization layer of the semiconductor device, in accordance with some embodiments. The non-limiting example in FIG. 5B is a variation of the example in FIG. 5A. Therefore, components in FIG. 5B that are the same or similar to those in FIG. 5A are given the same reference numbers, and description thereof is simplified or omitted.

In some embodiments, via layout pattern 514 prior to the application of the OPC process has a freeform shape that corresponds to having an irregular contour, being asymmetrical, or both. In some embodiments, via layout pattern 514 has a freeform contour based on reduction of a difference between the freeform contour and a region contour of the overlapped region (e.g., corresponding to overlapped region 430 in FIG. 4C). In some embodiments, the freeform contour via layout pattern 514 is based on fitting sidewalls of estimated patterns 532 and 538 that define the region contour of the overlapped region, and taking the constraints of various design rules and/or mask data preparation into consideration.

Moreover, via layout patterns 541, 542, 543, 544, 545, 546, and 547 correspond to a set of dummy layout patterns for the via layer of the semiconductor device. In some embodiments, each one of the set of dummy layout patterns has a corresponding freeform shape. In some embodiments, the set of dummy layout patterns (i.e., via layout patterns 541, 542, 543, 544, 545, 546, and 547) is within a reference distance from via layout pattern 514. In some embodiments, the reference distance corresponds to an OPC ambit of the OPC process to be applied to the via layout patterns 541, 542, 543, 544, 545, 546, and 547. In some embodiments, the set of dummy layout patterns (i.e., via layout patterns 541, 542, 543, 544, 545, 546, and 547) is omitted.

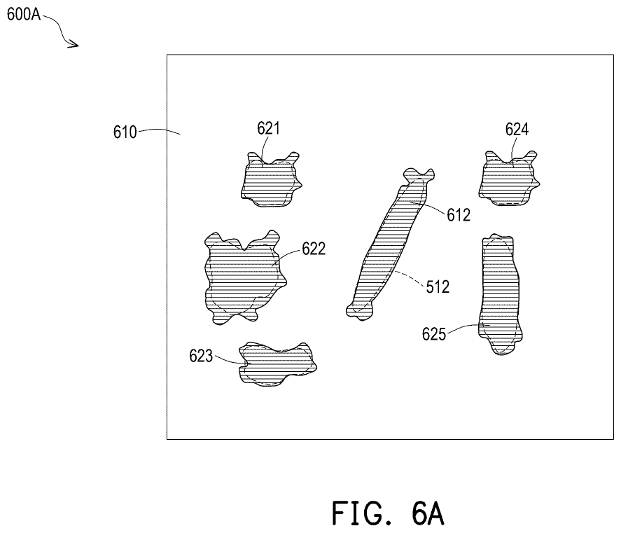

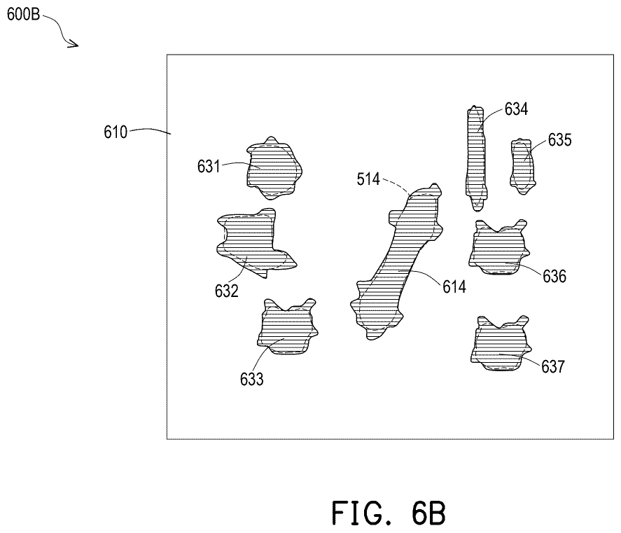

FIG. 6A is a plan view of a portion of a first photomask example 600A for a via layer of a semiconductor device based on the example in FIG. 5A, in accordance with some embodiments. In some embodiments, the via layout patterns in FIG. 5A (also included in FIG. 6A as dashed shapes for comparison) are further processed based on one or more processing stages of mask data preparation (e.g., mask data preparation 132 in FIG. 1), including an OPC process for example, and photomask 600A is manufactured according to the result of the mask data preparation based on the via layout patterns in FIG. 5A. The plan view of photomask 600A in FIG. 6A is a simplified plan view of a portion of photomask 600A, and some features of photomask 600A are simplified or omitted in FIG. 6A.

In FIG. 6A, photomask 600A includes a substrate 610 (e.g., a fused quartz substrate) and a via mask pattern structure 612 over substrate 610. In this example, via mask pattern structure 612 corresponds to a via layout pattern (e.g., layout pattern 512 in FIG. 5A and presented in FIG. 6A for comparison) included in a via layout diagram of the layout plan and indicative of a via structure of the semiconductor device connecting a first conductive structure (e.g., indicated by layout pattern 312 in FIG. 4A) under the via structure and a second conductive structure (e.g., indicated by layout pattern 412 in FIG. 4A) over the via structure. In this example, via layout pattern 512 has a curved shape prior to application of an OPC process, and the contour of via mask pattern structure 612 has additional bumps and dents compared to via layout pattern 512 as a result of one or more other stages of mask data preparation (e.g., including application of the OPC process).

In some embodiments, the first conductive structure corresponds to a first estimated pattern (e.g., estimated pattern 532 in FIG. 5A) derivable from a first layout pattern (e.g., layout pattern 312 in FIG. 4A) included in a first metallization layout diagram of the layout plan. In some embodiments, the second conductive structure corresponds to a second estimated pattern (e.g., estimated pattern 538 in FIG. 5A) derivable from a second layout pattern (e.g., layout pattern 412 in FIG. 4A) included in a second metallization layout diagram of the layout plan. In some embodiments, the first estimated pattern and the second estimated pattern overlap each other and define an overlapped region (e.g., overlapped region 430 in FIG. 4C). In some embodiments, via layout pattern 512 prior to the application of the OPC process is within the overlapped region.

In some embodiments, as described with reference to the example in FIG. 5A, via layout pattern 512 prior to the application of the OPC process has an elliptical shape. In some embodiments, via layout pattern 512 prior to the application of the OPC process has an elliptical contour that is obtained by resizing, positing, tilting, or a combination thereof, a base elliptical contour from a layout library based on reduction of a difference between the via layout pattern prior to the application of the OPC process and the overlapped region.

In some embodiments, photomask 600A further includes a set of dummy mask pattern structures 621, 622, 623, 624, and 625 over the substrate. In some embodiments, the set of dummy mask pattern structures correspond to a set of dummy layout patterns (e.g., via layout patterns 512, 521, 522, 523, 524, and 525 in FIG. 5A) included in the via layout diagram of the layout plan. In some embodiments, each one of the set of dummy layout patterns has a corresponding freeform shape.

FIG. 6B is a plan view of a portion of a second photomask example 600B for a via layer of a semiconductor device based on the example in FIG. 5B, in accordance with some embodiments. In some embodiments, the via layout patterns in FIG. 5B (also included in FIG. 6B as dashed shapes for comparison) are further processed based on one or more processing stages of mask data preparation (e.g., mask data preparation 132 in FIG. 1), including an OPC process for example, and photomask 600B is manufactured according to the result of the mask data preparation based on the via layout patterns in FIG. 5B. The plan view of photomask 600B in FIG. 6B is a simplified plan view of a portion of photomask 600B, and some features of photomask 600B are simplified or omitted in FIG. 6B.

In this non-limiting example, photomask 600B is a variation of photomask 600A, and components in FIG. 6B that are the same or similar to those in FIG. 6A are given the same reference numbers, and description thereof is simplified or omitted. In FIG. 6B, photomask 600B includes a substrate 610 (e.g., a fused quartz substrate) and a via mask pattern structure 614 over substrate 610. In this example via mask pattern structure 614 corresponds to a via layout pattern (e.g., layout pattern 514 in FIG. 5B and presented in FIG. 6B for comparison) included in a via layout diagram of the layout plan and indicative of a via structure of the semiconductor device connecting a first conductive structure (e.g., indicated by layout pattern 312 in FIG. 4A) under the via structure and a second conductive structure (e.g., indicated by layout pattern 412 in FIG. 4A) over the via structure. In this example, via layout pattern 514 has a curved shape prior to application of an OPC process, and via mask pattern structure 614 has bumps and dents compared to via layout pattern 512 as a result of one or more other stages of mask data preparation (including application of the OPC process).

In some embodiments, as described with reference to the example in FIG. 5B, via layout pattern 514 prior to the application of the OPC process has a freeform shape that corresponds to having an irregular contour, being asymmetrical, or both. In some embodiments, via layout pattern 514 prior to the application of the OPC process has a freeform contour based on reduction of a difference between the freeform contour and a region contour of the overlapped region.

In some embodiments, photomask 600B further includes a set of dummy mask pattern structures 631, 632, 633, 634, 635, 636, and 637 over the substrate. In some embodiments, the set of dummy mask pattern structures correspond to a set of dummy layout patterns (e.g., via layout patterns 514, 541, 542, 543, 544, 545, 546, and 547 in FIG. 5B) included in the via layout diagram of the layout plan. In some embodiments, each one of the set of dummy layout patterns has a corresponding freeform shape.

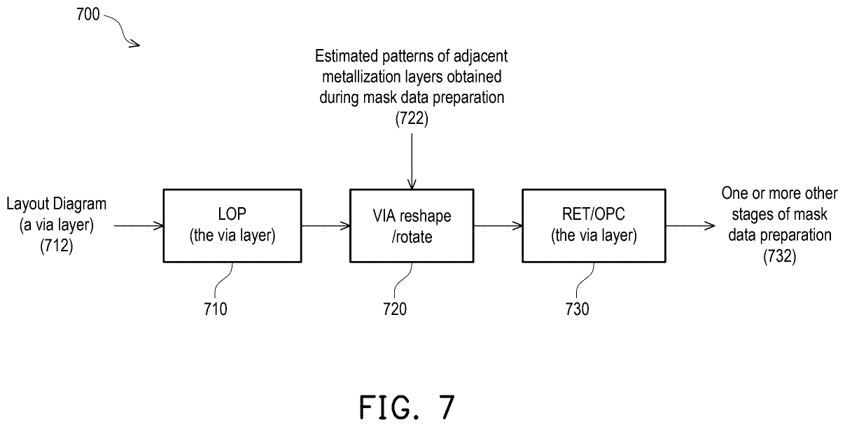

FIG. 7 is a block diagram of a portion of a mask data preparation process 700, in accordance with some embodiments. In some embodiments, mask data preparation process 700 is a variation of mask data preparation 132 in FIG. 1. In FIG. 7, mask data preparation process 700 includes various stages for processing a via layout diagram of a layout plan of a semiconductor device in view of the examples in FIGS. 4A-5B.

In FIG. 7, mask data preparation process 700 includes an LOP stage 710 for the via layer that corresponds to LOP stage 132a in FIG. 1. LOP stage 710 receives a layout diagram 712 of the via layer from a design house (e.g., design house 120) and outputs a refined layout diagram to a via reshape/rotate stage 720. In this example, via reshape/rotate stage 720 also receives the estimated patterns of adjacent metallization layers obtained during mask data preparation of the layout diagrams of the adjacent metallization layer (e.g., mask data preparation 132 for the adjacent metallization layer, represented by reference number 722 in FIG. 7). In some embodiments, via reshape/rotate stage 720 modifies the via layout patterns based on the approaches as described with respect to the examples in FIGS. 5A-5B. After stage 720, mask data preparation process 700 proceeds to a RET/OPC stage 730 (corresponding to RET stage 132b in FIG. 1) for the via layer and afterwards outputs the processed layout diagram to one or more other stages (e.g., stages 132c, 132d, and 132e in FIG. 1) of mask data preparation process 700 (represented by reference number 732 in FIG. 7).

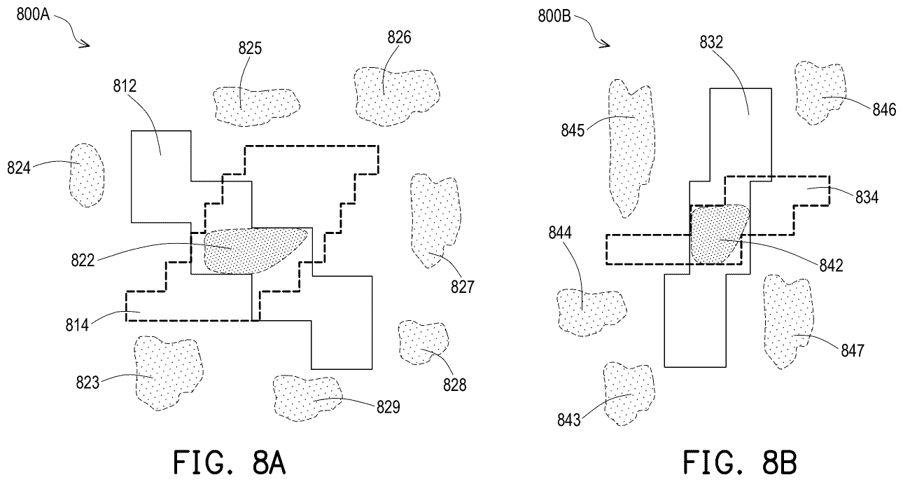

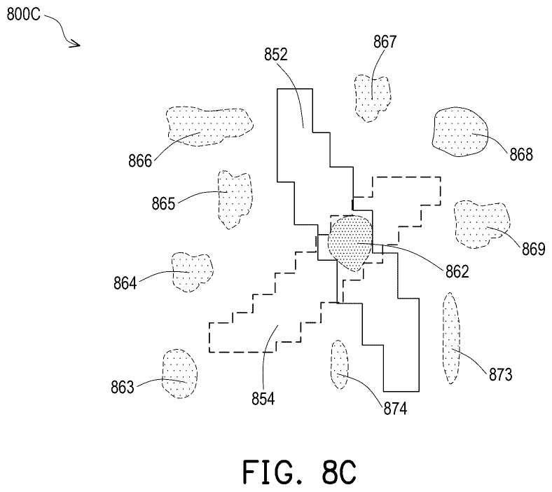

FIGS. 8A-8C are plan views of additional layout pattern examples 800A, 800B, and 800C for a first metallization layer, a second metallization layer, and a via layer having curved patterns, in accordance with some embodiments. In these non-limiting examples, the via layout patterns are based on the mask data preparation example in FIG. 5B.

In FIG. 8A, layout pattern example 800A includes a layout pattern 812 that is included in a first metallization layout diagram of a layout plan for a first metallization layer of the semiconductor device, and a layout pattern 814 that is included in a second metallization layout diagram of the layout plan for a second metallization layer of the semiconductor device. In this example, layout patterns 812 and 814 have Manhattanized curvilinear shapes. Moreover, layout pattern example 800A includes a via layout pattern 822 and dummy patterns 823-829 that are included in a via layout diagram of the layout plan for a via layer of the semiconductor device. In some embodiments, via layout pattern 822 is indicative of a via structure electrically connecting a conductive structure indicated by layout pattern 812 and a conductive structure indicated by layout pattern 814. In this example, via layout pattern 822 is based on fitting a freeform contour of the layout pattern via layout pattern 822 and a region contour of an overlapped region defined by estimated patterns derived from layout patterns 812 and 814.

In FIG. 8B, layout pattern example 800B includes a layout pattern 832 that is included in a first metallization layout diagram of a layout plan for a first metallization layer of the semiconductor device, and a layout pattern 834 that is included in a second metallization layout diagram of the layout plan for a second metallization layer of the semiconductor device. In this example, layout patterns 832 and 834 have Manhattanized curvilinear shapes. Moreover, layout pattern example 800B includes a via layout pattern 842 and dummy patterns 843-847 that are included in a via layout diagram of the layout plan for a via layer of the semiconductor device. In some embodiments, via layout pattern 842 is indicative of a via structure electrically connecting a conductive structure indicated by layout pattern 832 and a conductive structure indicated by layout pattern 834. In this example, via layout pattern 842 is based on fitting a freeform contour of the layout pattern via layout pattern 842 and a region contour of an overlapped region defined by estimated patterns derived from layout patterns 832 and 834.

In FIG. 8C, layout pattern example 800C includes a layout pattern 852 that is included in a first metallization layout diagram of a layout plan for a first metallization layer of the semiconductor device, and a layout pattern 854 that is included in a second metallization layout diagram of the layout plan for a second metallization layer of the semiconductor device. In this example, layout patterns 852 and 854 have Manhattanized curvilinear shapes. Moreover, layout pattern example 800C includes a via layout pattern 862 and dummy patterns 863-874 that are included in a via layout diagram of the layout plan for a via layer of the semiconductor device. In some embodiments, via layout pattern 862 is indicative of a via structure electrically connecting a conductive structure indicated by layout pattern 852 and a conductive structure indicated by layout pattern 834. In this example, via layout pattern 862 is based on fitting a freeform contour of the layout pattern via layout pattern 862 and a region contour of an overlapped region defined by estimated patterns derived from layout patterns 852 and 854.

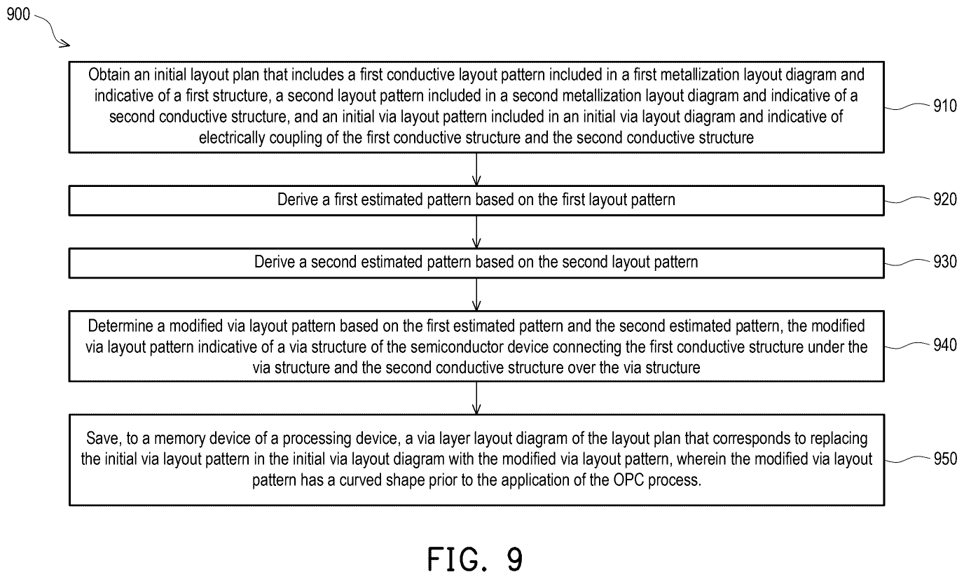

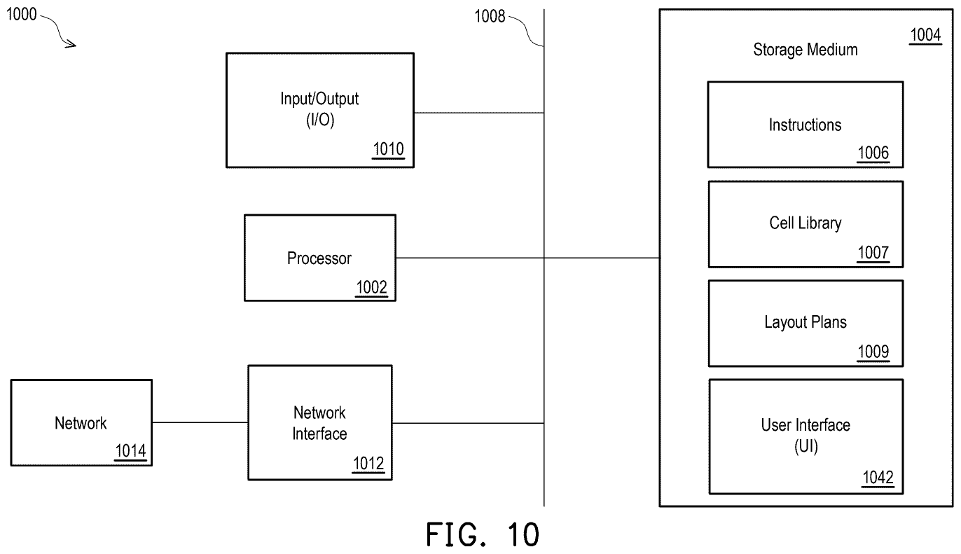

FIG. 9 is a flowchart of a method 900 of generating a via layout diagram of a layout plan of a semiconductor device prior to application of an OPC process, in accordance with some embodiments. Method 900 is implementable, for example, using EDA system 1000 (FIG. 10, discussed below) and an integrated circuit (IC), manufacturing system 100 in FIG. 1, in accordance with some embodiments. In some embodiments, method 900 is part of a mask data preparation process, such as mask data preparation 132 in FIG. 1 or mask data preparation process 700 in FIG. 7. Examples of a layout diagram which can be generated according to method 900 includes layout patterns described with respect to the examples in FIGS. 5A-5B and 8A-8C. In FIG. 9, method 900 includes blocks 910-950.

At block 910, an initial layout plan (e.g., layout plan 122 in FIG. 1 or a layout plan including layout patterns in FIG. 4A) is obtained. In some embodiments, the initial layout plan includes a first layout pattern (e.g., layout pattern 312 in FIG. 4A) included in a first metallization layout diagram and indicative of a first conductive structure and a second layout pattern (e.g., layout pattern 412 in FIG. 4A) included in a second metallization layout diagram and indicative of a second conductive structure. In some embodiments, the initial layout plan further includes an initial via layout pattern (e.g., layout pattern 416 in FIG. 4A) included in an initial via layout diagram and indicative of electrically coupling of the first conductive structure and the second conductive structure.

At block 920, a first estimated pattern (e.g., estimated pattern 322 in FIG. 4B) is derived based on the first layout pattern. At block 930, a second estimated pattern (e.g., estimated pattern 422 in FIG. 4B) is derived based on the second layout pattern. In some embodiments, the first estimated pattern and the second estimated pattern overlap each other and define an overlapped region (e.g., overlapped region 430 in FIG. 4C).

At block 940, a modified via layout pattern (e.g., via layout pattern 512 in FIG. 5A or via layout pattern 514 in FIG. 5B, in view of via layout patterns 822, 842, and 862 in FIGS. 8A-8C) based on the first estimated pattern and the second estimated pattern. In some embodiments, the modified via layout pattern is indicative of a via structure of the semiconductor device connecting the first conductive structure under the via structure and the second conductive structure over the via structure. In some embodiments, the modified via layout pattern has a curved shape prior to the application of the OPC process. In some embodiments, the modified via layout pattern is within the overlapped region defined by the first estimated pattern and the second estimated pattern.

In some embodiments, in view of the example in FIG. 5A, the modified via layout pattern has an elliptical shape. In some embodiments, the modified via layout pattern is determined by resizing positioning, tilting, positioning, or a combination thereof, a base elliptical contour as an elliptical contour of the modified via layout pattern based on reduction of a difference between the modified via layout pattern and the overlapped region.

In some embodiments, in view of the example in FIG. 5B, the modified via layout pattern has a freeform shape that corresponds to having an irregular contour, being asymmetrical, or both. In some embodiments, the modified via layout pattern is determined based on determining a freeform contour of the modified via layout pattern based on reduction of a difference between the freeform contour and a region contour of the overlapped region.

In some embodiments, method 900 further includes determining a set of dummy layout patterns (e.g., dummy patterns 521-525 in FIG. 5A or dummy patterns 541-547 in FIG. 5B) indicative of a set of dummy via structures. In some embodiments, each one of the set of dummy layout patterns has a corresponding freeform shape. In some embodiments, the set of dummy layout patterns is within a reference distance from the modified via layout pattern. In some embodiments, the reference distance corresponds to an OPC ambit of the OPC process.

At block 950, the via layout diagram of the layout plan is saved to a memory device of a processing device. In some embodiments, the via layout diagram of the layout plan corresponds to replacing the initial via layout pattern in the initial via layout diagram with the modified via layout pattern in view of the examples in FIGS. 4A-5B.

FIG. 10 is a block diagram of an electronic design automation (EDA) system 1000 in accordance with some embodiments.

In some embodiments, EDA system 1000 includes an automatic placement and routing (APR) system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores library 1007 of standard cells including such standard cells as disclosed herein. In one or more embodiments, storage medium 1004 stores one or more layout diagrams 1009 corresponding to one or more layouts disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, or the like.

In some aspects, a photomask for a layer of a semiconductor device based on a layout plan of the semiconductor device includes a substrate and a via mask pattern structure over the substrate. The via mask pattern structure corresponds to a via layout pattern included in a via layout diagram of the layout plan and indicative of a via structure of the semiconductor device connecting a first conductive structure under the via structure and a second conductive structure over the via structure. The via layout pattern has a curved shape prior to application of an optical proximity correction (OPC) process.

In some aspects, a method of generating a via layout diagram of a layout plan of a semiconductor device prior to application of an optical proximity correction (OPC) process includes obtaining an initial layout plan that includes a first layout pattern included in a first metallization layout diagram and indicative of a first conductive structure, a second layout pattern included in a second metallization layout diagram and indicative of a second conductive structure, and an initial via layout pattern included in an initial via layout diagram and indicative of electrically coupling of the first conductive structure and the second conductive structure. The method includes deriving a first estimated pattern based on the first layout pattern, deriving a second estimated pattern based on the second layout pattern, and determining a modified via layout pattern based on the first estimated pattern and the second estimated pattern. The modified via layout pattern is indicative of a via structure of the semiconductor device connecting the first conductive structure under the via structure and the second conductive structure over the via structure. The method further includes saving, to a memory device of a processing device, the via layout diagram of the layout plan that corresponds to replacing the initial via layout pattern in the initial via layout diagram with the modified via layout pattern. The modified via layout pattern has a curved shape prior to the application of the OPC process.

In some aspects, a processing device for generating a via layout diagram of a layout plan of a semiconductor device prior to application of an optical proximity correction (OPC) process includes a memory device processing circuitry coupled to the memory device. The processing circuity is configured to obtain an initial layout plan that includes a first layout pattern included in a first metallization layout diagram and indicative of a first conductive structure, a second layout pattern included in a second metallization layout diagram and indicative of a second conductive structure, and an initial via layout pattern included in an initial via layout diagram and indicative of electrically coupling of the first conductive structure and the second conductive structure. The processing circuity is configured to derive a first estimated pattern based on the first layout pattern, derive a second estimated pattern based on the second layout pattern, and determine a modified via layout pattern based on the first estimated pattern and the second estimated pattern. The modified via layout pattern is indicative of a via structure of the semiconductor device connecting the first conductive structure under the via structure and the second conductive structure over the via structure. The processing circuity is further configured to save, to the memory device, the via layout diagram of the layout plan that corresponds to replacing the initial via layout pattern in the initial via layout diagram with the modified via layout pattern. The modified via layout pattern has a curved shape prior to the application of the OPC process.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A photomask for a layer of a semiconductor device based on a layout plan of the semiconductor device, comprising:
a substrate; and
a via mask pattern structure over the substrate, the via mask pattern structure corresponding to a via layout pattern included in a via layout diagram of the layout plan and indicative of a via structure of the semiconductor device connecting a first conductive structure under the via structure and a second conductive structure over the via structure,
wherein
the via layout pattern has a curved shape prior to application of an optical proximity correction (OPC) process.

2. The photomask of claim 1, wherein
the first conductive structure corresponds to a first estimated pattern derivable from a first layout pattern included in a first metallization layout diagram of the layout plan,
the second conductive structure corresponds to a second estimated pattern derivable from a second layout pattern included in a second metallization layout diagram of the layout plan,
the first estimated pattern and the second estimated pattern overlap each other and define an overlapped region, and
the via layout pattern prior to the application of the OPC process is within the overlapped region.

3. The photomask of claim 2, wherein
the via layout pattern prior to the application of the OPC process has an elliptical shape.

4. The photomask of claim 2, wherein
the via layout pattern prior to the application of the OPC process has an elliptical contour that is obtained by resizing, positing, tilting, or a combination thereof, a base elliptical contour based on reduction of a difference between the via layout pattern prior to the application of the OPC process and the overlapped region.

5. The photomask of claim 2, wherein
the via layout pattern prior to the application of the OPC process has a freeform shape that corresponds to having an irregular contour, being asymmetrical, or both.

6. The photomask of claim 2, wherein
the via layout pattern has a freeform contour based on reduction of a difference between the freeform contour and a region contour of the overlapped region.

7. The photomask of claim 1, further comprising:
a set of dummy mask pattern structures over the substrate, the set of dummy mask pattern structures corresponding to a set of dummy layout patterns included in the via layout diagram of the layout plan, and each one of the set of dummy layout patterns has a corresponding freeform shape.

8. A method of generating a via layout diagram of a layout plan of a semiconductor device prior to application of an optical proximity correction (OPC) process, comprising:
obtaining an initial layout plan that includes
a first layout pattern included in a first metallization layout diagram and indicative of a first conductive structure,
a second layout pattern included in a second metallization layout diagram and indicative of a second conductive structure, and
an initial via layout pattern included in an initial via layout diagram and indicative of electrically coupling of the first conductive structure and the second conductive structure;
deriving a first estimated pattern based on the first layout pattern;
deriving a second estimated pattern based on the second layout pattern;
determining a modified via layout pattern based on the first estimated pattern and the second estimated pattern, the modified via layout pattern indicative of a via structure of the semiconductor device connecting the first conductive structure under the via structure and the second conductive structure over the via structure; and
saving, to a memory device of a processing device, the via layout diagram of the layout plan that corresponds to replacing the initial via layout pattern in the initial via layout diagram with the modified via layout pattern,
wherein
the modified via layout pattern has a curved shape prior to the application of the OPC process.

9. The method of claim 8, wherein
the first estimated pattern and the second estimated pattern overlap each other and define an overlapped region, and
the modified via layout pattern is within the overlapped region.

10. The method of claim 9, wherein
the modified via layout pattern has an elliptical shape.

11. The method of claim 9, wherein
the determining the modified via layout pattern comprises resizing positioning, tilting, positioning, or a combination thereof, a base elliptical contour as an elliptical contour of the modified via layout pattern based on reduction of a difference between the modified via layout pattern and the overlapped region.

12. The method of claim 9, wherein
the modified via layout pattern has a freeform shape that corresponds to having an irregular contour, being asymmetrical, or both.

13. The method of claim 9, wherein
the determining the modified via layout pattern comprises determining a freeform contour of the modified via layout pattern based on reduction of a difference between the freeform contour and a region contour of the overlapped region.

14. The method of claim 8, further comprising:
determining a set of dummy layout patterns indicative of a set of dummy via structures, each one of the set of dummy layout patterns has a corresponding freeform shape,
wherein
the saving, to the memory device of the processing device, the via layout diagram of the layout plan comprises including the set of dummy layout patterns in the via layout diagram of the layout plan.

15. A processing device for generating a via layout diagram of a layout plan of a semiconductor device prior to application of an optical proximity correction (OPC) process, comprising:
a memory device; and
processing circuitry coupled to the memory device and configured to:
obtain an initial layout plan that includes
a first layout pattern included in a first metallization layout diagram and indicative of a first conductive structure,
a second layout pattern included in a second metallization layout diagram and indicative of a second conductive structure, and
an initial via layout pattern included in an initial via layout diagram and indicative of electrically coupling of the first conductive structure and the second conductive structure;
derive a first estimated pattern based on the first layout pattern;
derive a second estimated pattern based on the second layout pattern;
determine a modified via layout pattern based on the first estimated pattern and the second estimated pattern, the modified via layout pattern indicative of a via structure of the semiconductor device connecting the first conductive structure under the via structure and the second conductive structure over the via structure; and
save, to the memory device, the via layout diagram of the layout plan that corresponds to replacing the initial via layout pattern in the initial via layout diagram with the modified via layout pattern,
wherein
the modified via layout pattern has a curved shape prior to the application of the OPC process.

16. The processing device of claim 15, wherein
the first estimated pattern and the second estimated pattern overlap each other and define an overlapped region, and
the modified via layout pattern is within the overlapped region.

17. The processing device of claim 16, wherein
the modified via layout pattern has an elliptical shape.

18. The processing device of claim 16, wherein
the processing circuitry configured to determine the modified via layout pattern is further configured to resize, position, tilt, or a combination thereof, a base elliptical contour as an elliptical contour of the modified via layout pattern based on reduction of a difference between the modified via layout pattern and the overlapped region.

19. The processing device of claim 16, wherein
the modified via layout pattern has a freeform shape that corresponds to having an irregular contour, being asymmetrical, or both.

20. The processing device of claim 19, wherein
the processing circuitry configured to determine the modified via layout pattern is further configured to determine a freeform contour of the modified via layout pattern based on reduction of a difference between the freeform contour and a region contour of the overlapped region.
